(19) United States
(12) Patent Application Publication
(10) Pub. No.: US 2006/0275542 A1
(43) Pub. Date: Dec. 7, 2006

(54) Deposition of uniform layer of desired material

(75) Inventors: Rajesh V. Mehta, Rochester, NY (US); Ramesh Jagannathan, Rochester, NY (US); Bradley M. Houghtaling, Rochester, NY (US); Robert Link, Webster, NY (US); Kelly S. Robinson, Fairport, NY (US); Ross A. Sprout, Rochester, NY (US); Kenneth J. Reed, Rochester, NY (US); Alok Verma, Rochester, NY (US); Scott B. Mahon, Rochester, NY (US); Robledo O. Gutierrez, Rochester, NY (US); Thomas N. Blanton, Rochester, NY (US); Jill E. Fornalik, Rochester, NY (US)

Correspondence Address: Patent Legal Staff;Eastman Kodak Company, 343 State Street, Rochester, NY, 14650-2201, US

(73) Assignee: Eastman Kodak Company

(21) Appl. No.: 11/143,180

(22) Filed: Jun. 2, 2005

(51) Int. Cl. B05D 1/12

(52) U.S. Cl. 427/180

(57) ABSTRACT

A process for the deposition of a thin film of a desired material on a surface comprising: (i) providing a continuous stream of amorphous solid particles of desired material suspended in at least one carrier gas, the solid particles having a volume-weighted mean particle diameter of less than 500 nm, at an average stream temperature below the glass transition temperature of the solid particles of desired material, (ii) passing the stream provided in (i) into a heating zone, and heating the stream in the heating zone to elevate the average stream temperature to above the glass transition temperature of the solid particles of desired material, wherein no substantial chemical transformation of the desired material occurs due to heating of the desired material, (iii) exhausting the heated stream from the heating zone through at least one distributing passage, at a rate substantially equal to its rate of addition to the heating zone in step (ii), wherein the carrier gas does not undergo a thermodynamic phase change upon passage through heating zone and distribution passage, and (iv) exposing a receiver surface that is at a temperature below the temperature of the heated stream to the exhausted flow of the heated stream, and depositing particles of the desired material to form a thin uniform layer of the desired material on the receiver surface.

### CROSS-REFERENCE TO RELATED APPLICATION

Reference is made to concurrently filed, co-pending application U.S. Ser. No. ______ (Kodak Docket No. 89214) by Rajesh V. Mehta et al entitled “PROCESS FOR MAKING AN ORGANIC LIGHT-EMITTING DEVICE” filed simultaneously herewith, the disclosure of which is incorporated by reference herein.

### FIELD OF THE INVENTION

This invention relates generally to deposition technologies, and more particularly, to a technology to create a uniform thin film by delivering a flow of fine particulate material onto a receiver.

### BACKGROUND OF THE INVENTION

Deposition technologies are typically defined as technologies that deposit functional materials dissolved and/or dispersed in a fluid onto a receiver (also commonly known as substrate etc.).

Thermal spray or plasma deposition methods involve heating metallic and nonmetallic feedstock solid particles to a molten or plastic state, and propelling the heated particles onto a substrate to form a coating. The heat source typically is a combustion flame, a plasma jet, or an arc struck between two consumable wires. The substrate can be kept at relatively low temperature by suitable cooling devices. Methods and apparatus for thermal spray are well known, being reviewed, for example, by Fauchais et al. in “Quo Vadis Thermal spraying” J. of Thermal Spray Technology, (2001) 10: 44-66. They are also described, for example, in U.S. Pat. Nos. 4,869,936; 5,080,056; 5,198,308; 5,271,967; 5,312,653; and 5,328,763, which are incorporated by reference herein.

In current industrial practice, the powders used to deposit metal, ceramic or composite coatings by thermal spray or plasma deposition consist of particles in the range from 5 to 50 microns in diameter. During the short residence time in the flame or plasma, the particles are rapidly heated to form a spray of partially or completely melted droplets. The large impact forces created as these particles arrive at the substrate surface promote strong particle-substrate adhesion and the formation of a dense coating of almost any desired material. The coatings range in thickness from 25 microns to several millimeters, and are formed at relatively high deposition rates.

Generally, the conventional powders used in thermal spray coating are produced by a series of steps, involving ball milling, mechanical blending, high temperature reaction, and occasionally spray drying using a binder. Powder delivery systems in thermal spray technology are designed to work with powder agglomerates with particle size in the range from 5 to 25 microns, and the minimum size of the constituent grains or particles in conventional powders is typically in the range of 1 to 0.5 microns. In contrast, for nanostructured materials, the size of the constituent grains or particles is in the range from 1 to 100 nanometers. As such, synthesized nanoparticle powders are thus generally unsuitable for direct use in conventional thermal spray coating processes.

U.S. Pat. No. 6,025,034 relates to methods whereby reprocessed nanoparticle powder feeds, nanoparticle liquid suspensions, and metalorganic liquids are used in a thermal spray deposition process for the fabrication of nanostructured coatings of metals, ceramics, and their composites. The methods essentially rely on ultrasonic agitation to generate micron-sized solid or liquid particles from its feed material so that they can be fed directly into conventional thermal spray equipment. In case of nanoparticle powder feed, with typical particle size in the range of 3-30 nanometer, the loosely agglomerated powders are dispersed in a suitable solvent by ultrasonic agitation to form a colloidal suspension or slurry. This nanoparticle suspension or slurry is then introduced, along with liquid kerosene fuel, directly into the combustion zone of a High Velocity Oxygen Fuel (HVOF) gun via the liquid feed. Alternatively, the suspension or slurry is introduced in the form of an aerosol into the gas feed of a plasma or HVOF gun. Characteristics of this method are that the particles rapidly heat up in a short distance from the gun nozzle and almost instantaneously achieve the velocity of the gas stream, which is in the supersonic range. In some cases, the nanoparticles vaporize, prior to condensation on the substrate. In this case, the method becomes in effect a very high rate chemical vapor deposition process. In another embodiment, liquid metalorganic chemical precursors are directly injected into the combustion flame of a plasma thermal spray device, whereby nanoparticle synthesis, nanoparticle melting, and nanoparticle quenching onto a substrate are performed in a single operation. Two significant limitations of this approach are apparent: (1) it is limited to metal, ceramics, and their composites, and (2) processes occurring at the scale of micron-sized liquid particles can only provide a limited control of the nanostructural details of the coating such as porosity, size and composition of segregated regions, and defect level.

WO 98/36888 teaches a liquid phase process for preparing single-phase powder particles where an ultrasonic aerosol generator is used to aerosolize a liquid feed that is then passed through a pyrolyzing furnace to form particles. The mean particle size range is between 0.1 and 4 microns. In a separate embodiment, the disclosure also teaches making of composite particles where the first phase powder particles are generated via ultrasonication of a precursor liquid feed and subsequently coated with a second phase material. The average coating thickness is between 1 and 100 nm. However, the disclosure deals only with ultrasonically generated liquid droplets suspended in a carrier gas as the feed to the pyrolyzing furnace, not nanometer sized solid particles, and addresses only the coating of particles generated by the process.

Leivo et al. describe in “Properties of Thermally Sprayed Fluoropolymer PVDF, ECTFE, PFA and FEP Coatings” Progress in Organic Coatings, (2004), 49:69-73, high quality coatings of fluoropolymers by conventional flame and plasma spraying processes. Such thermal spray techniques are advantaged because unlike the conventional electrostatic powder coating methods, they are one-step methods where post-heat treatments are not required. However, the feed powder has to meet specific requirements on particle size and distribution. For example, desired size range for polymers is 50-200 micron: finer particles are not desirable because they easily overheat and burn in the high temperature regions of the process.

Physical and chemical vapor deposition processes are also convenient thermal deposition methods of creating thin film and nano-structured materials having unique chemical, physical, electrical and optical properties and useful devices therefrom. A very wide range of metals, inorganic and organic compounds can be deposited in a vacuum, or near vacuum with controlled concentrations of either specific reactive gases or non-reactive gases by these methods. In physical vapor deposition (PVD), a source material is heated to a temperature so as to cause vaporization and produce a vapor plume to form a thin film upon deposition on a surface of a substrate in a vacuum environment. Such methods are well known, for example, U.S. Pat. No. 2,447,789 and EP 0 982 411. In some cases, such as in U.S. Pat. No. 6,337,102, vapors are conveyed in combination with carrier gases into the vacuum deposition chamber and ultimately to the substrate surface. The film formation in PVD methods is generally believed to occur by vapor condensation.

In addition to film formation from molecular vapors, thin films can also be assembled from clusters of molecules. The photoluminescence properties of thin films of Alq₃ deposited under high vacuum on Si substrates by neutral or ionized cluster beam deposition (NCBD or ICBD) have been reported recently by Kim et al. in “Characterization and Luminescence Properties of Alq₃ films Grown by Ionized Cluster Beam Deposition, Neutral Cluster Beam Deposition and Thermal Evaporation”, Thin Solid Films (2001) 78-81:398-399. Such processes have to employ high vacuum conditions in the deposition chamber to generate the desired film.

A typical chemical vapor deposition (CVD) process uses a vapor transport mechanism in which the gaseous reactants decompose and recombine to form the desired thin film where heated substrate facilitates decomposition and reaction. U.S. Pat. Nos. 6,013,318; 5,997,956; 5,863,604; 5,858,465; 5,652,021 and 6,368,665 are directed to combustion chemical vapor deposition or controlled atmosphere chemical vapor deposition processes. These processes are open atmosphere, generally atmospheric pressure deposition techniques. These processes are suitable for coating substrates of almost any size because the substrate need not be confined in a chamber or furnace, as is the case in conventional CVD processes. One common method used to generate vapor for CVD is to bubble a carrier gas through a heated liquid reagent. Other methods involve atomization of liquid reagents to form aerosols, typically having droplet diameters between 0.1 and 10 micron, as described, for example, in U.S. Pat. No. 5,278,138. Although CVD processes use vapor feed, nanometer sized particles may form as reaction products and deposit on the target surface as described, for example, in U.S. Pat. No. 6,652,967, and by P. Han and T. Yoshida in “Numerical investigation of thermophoretic effects on cluster transport during thermal plasma deposition process” J. Applied Physics, (2002) 91:1814-1818.

Copending, commonly-assigned U.S. Ser. No. 10/805,980 (Docket 87180) discloses a method for vaporizing organic materials onto a surface, to form a film comprising: providing a quantity of organic material in a fluidized powdered form; metering the powdered organic material and directing a stream of such fluidized powder onto a permeable member; heating the permeable member so that as the stream of fluidized powder passes through it flash vaporizes; collecting the vaporized organic material and passing it through manifolds to direct it onto a surface to form a film. In another embodiment, the organic material is provided in a fluidized powdered form by evaporation or rapid expansion of a solution of the organic material in a supercritical solvent, and then flash vaporized. This method is essentially a PVD process and relies critically on controlled metering of fluidized powder, its flash vaporization, and controlled deposition of vapor under vacuum, e.g. a pressure of 1 torr or less, onto a substrate to form a film. Also, the applicability of such a process where the substrate is at or near ambient atmospheric pressures is unknown but likely to be problematic: depending on the vaporization rate, it may be difficult, if not impossible, to achieve flash vaporization, and once formed, vapor may transform into particles in its flight to the substrate and that may have detrimental effect on the performance of the film in the final device.

U.S. Pat. No. 4,734,227 describes a process where solid films are deposited, by dissolving a solid material into a supercritical fluid solution at an elevated pressure and then rapidly expanding the solution through a heated nozzle having a short orifice into a region of relatively low pressure. This produces a molecular spray that is directed against a substrate to deposit a solid thin film thereon. Heating of the nozzle is required to prevent the possible clogging of the orifice due to dramatic cooling accompanying the expansion. In another embodiment, the temperature of the solution and nozzle is elevated above the melting point of the solute, which is preferably a polymer, and simultaneously above the critical point of the solvent, and the solution is maintained at a pressure such that, during expansion, the solute precipitates out of solution within the nozzle in a liquid state so that the polymer forms fibers upon discharge from the nozzle. The elevated heating of the nozzle in this case is needed not only to prevent the possible clogging caused by cooling during expansion, but also to prevent solid particles of polymers from forming and clogging the nozzle. Thus, heated nozzles are generally used in such processes for preventing solid particles from forming altogether during the passage of the supercritical solution stream through the nozzle orifice.

U.S. H1839 discloses a batch process employing a heated nozzle and expansion chamber, where both are heated to a temperature where solvent exists in its vapor form at the prevailing pressure. Heating of the expansion chamber in this case is for preventing solvent from condensing and redissolving the solute. Also, the disclosure is directed primarily to micronization of polymeric wax particles and not their deposition onto a receiver for creating a coating or a film.

U.S. Pat. No. 5,171,613 is directed to an improved spraying apparatus for coating substrates with a coating material and supercritical fluid, to prevent undesirable premature cooling of the coating mixture which might detrimentally affect the final coating on the substrate. The spray temperature used is a function of the coating material, the supercritical fluid being used, and the concentration of supercritical fluid in the coating mixture. The minimum spray temperature is generally at or slightly below the critical temperature of the supercritical fluid. The maximum temperature is the highest temperature at which the components of the coating mixture are not significantly thermally degraded during the time that the coating mixture is at that temperature. If the supercritical fluid is supercritical carbon dioxide fluid, because the supercritical fluid escaping from the spray nozzle could cool to the point of condensing solid carbon dioxide and any ambient water vapor present due to high humidity in the surrounding spray environment, the spray composition is preferably heated prior to atomization. The minimum spray temperature is about 31 degree C. The maximum temperature is determined by the thermal stability of the components in the coating mixture, typically between 35 degree and 90 degree C. The spray nozzle in this process is heated primarily to maintain a feathered spray pattern as the coating mixture is sprayed, not for improving the deposition efficiency of previously formed solid particles or for altering the microstructure of the coating.

U.S. Pat. No. 5,639,441 describes a process where an immiscible mixture of two fluids, one of them in its supercritical state, is expanded to form a gas-borne dispersion of liquid droplets or solid particles having an average diameter less than 6.5 micron. The disclosure claims deposition of these particles on a substrate to form a film but provides no details as to how to accomplish this.

Copending, commonly assigned U.S. Ser. No. 10/815,026 (Docket 87485) discloses a compressed fluid based continuous coating process that is based on anti-solvent properties of supercritical medium for particle generation. It envisions a number of ways to deposit desired material onto the receiver surface that is located downstream of the expansion nozzle. These include approaches where supersonic flow through an expansion nozzle is directly used for coating the functional material onto a receiver substrate, where additional electromagnetic or electrostatic means are employed to interact with the nozzle exhaust to deflect the particles to the coating surface, and where additional flow means are employed to either control the momentum, or temperature, of the exhaust stream.

A significant difficulty with coating technologies based on expansion of supercritical fluids is that particles in the range from 1-500 nm are difficult to deposit on a surface since their extremely low mass causes them to remain entrained in the expansion gas. U.S. Ser. No. 10/815,026 (Docket 87485) teaches specific corona charging methods that increase the deposition rate of the desired particles. U.S. Pat. No. 6,756,084 also discloses an electrostatic charging method for depositing solid solute particles onto a substrate to form a film. But these methods are still problematic: the charging and deposition efficiencies are particularly low at the low particle sizes; high performance dense films are very difficult to obtain; and since such electrostatic processes rely on the ionization of gaseous medium resulting from a high voltage point discharge across a small gap, sensitive materials can be damaged very easily.

With specific regard to organic thin film formation for applications directed to organic electronics such as Organic Light Emitting Devices (OLEDs), organic photovoltaic cells, electrically pumped lasers and organic field effect transistors (OFETs), a number of review articles have addressed the subject (e.g., Stephen R. Forrest in Chem.Rev (1997), 97: 1793-1896; Hooks, Fritz and Ward in Adv. Mater. (2001) 13, 227; G. Witte and C. Woll in Journal of Materials Research (2004) 19(7): 1889-1916). Organic molecules, unlike atoms, have a pronounced shape anisotropy. Hence, the structure of organic thin films is defined by a number of factors including the position of the molecule, and its molecular orientation. The molecules also can deform when brought into contact with the substrate. Also, many organic compounds exhibit polymorphism. The extent of bonding interaction of the deposited material with the substrate will also play a role in determining the structure (oriented vs. amorphous) of the organic thin film. Also, it is not uncommon to observe long-range order in vapor deposited films for extended polycyclic aromatic systems (G. Witte and C. Woell, Phase Transitions (2003) 76(4-5): 291-305). Localized molecular order (i.e. short range) in an otherwise amorphous film can come about when there are strong intermolecular dipole-dipole interactions (see for example M. A. Baldo et al. in Chemical Physics Letters, 2001 347: 297-303). Interestingly, the converse situation, namely, long-range order superimposed over short-range disorder (amorphous domains) appears not yet to have been observed. Such a film would be expected to exhibit unusual optical, thermal, or mechanical properties modulated by size confinement that would depend upon the amorphous domain size.

Thus, there is a continuing need for improved methods for depositing solid particles that are carried in a stream of carrier gas, where the particle size is in the range from 1-500 nm, to achieve reproducible, high-quality deposition of desired materials.

### SUMMARY OF THE INVENTION

In accordance with one embodiment, the invention is directed towards a process for the deposition of a thin film of a desired material on a surface comprising:

(i) providing a continuous stream of amorphous solid particles of desired material suspended in at least one carrier gas, the solid particles having a volume-weighted mean particle diameter of less than 500 nm, at an average stream temperature below the glass transition temperature of the solid particles of desired material,

(ii) passing the stream provided in (i) into a heating zone, and heating the stream in the heating zone to elevate the average stream temperature to above the glass transition temperature of the solid particles of desired material, wherein no substantial chemical transformation of the desired material occurs due to heating of the desired material,

(iii) exhausting the heated stream from the heating zone through at least one distributing passage, at a rate substantially equal to its rate of addition to the heating zone in step (ii), wherein the carrier gas does not undergo a thermodynamic phase change upon passage through heating zone and distribution passage, and

(iv) exposing a receiver surface that is at a temperature below the temperature of the heated stream to the exhausted flow of the heated stream, and depositing particles of the desired material to form a thin uniform layer of the desired material on the receiver surface.

In accordance with various embodiments, the present invention provides technologies that permit functional material deposition of ultra-small particles; that permit high speed, accurate, and uniform deposition of a functional material on a receiver; that permit high speed, accurate, and precise patterning of a receiver; that permit the creation of ultra-small features on the receiver when used in conjunction with a mask; that permit high speed, accurate, and precise coating of a receiver using a mixture of one or more nanometer sized functional material dispersed in a carrier fluid; that permit high speed, accurate, and precise coating of a receiver using a mixture of one or more nanometer sized functional material dispersed in a fluid where the nanometer sized functional materials are continuously created; that permit high speed, accurate, and precise coating of a receiver using a mixture of nanometer sized one or more functional material dispersed in a fluid where the nanometer sized functional materials are continuously created as a dispersion in the fluid in a vessel containing a mixing device or devices; and that permits high speed, accurate, and precise coating of a receiver that has improved material deposition capabilities.

### BRIEF DESCRIPTION OF THE DRAWINGS

FIG. 1 shows a 3-dimensional display of the sample surface obtained in Example 1.

FIG. 2(A) shows the 3-dimensional display of the sample surface obtained in Example 2.

FIG. 2(B) shows a WYCO NT1000 instrument signal near a carefully created edge on the sample surface obtained in Example 2.

FIG. 2(C) shows a high-angle X-ray diffraction pattern of the film obtained in Example 2.

FIG. 2(D) shows a low-angle X-ray diffraction pattern of the film obtained in Example 2.

FIG. 3 shows a WYCO NT1000 instrument signal near a carefully created edge on the sample surface obtained in Example 3.

FIG. 4 shows a WYCO NT1000 instrument signal near a carefully created edge on the sample surface obtained in Example 4.

FIG. 5 shows a low-angle X-ray diffraction pattern of the film obtained in Example 5.

FIG. 6A shows a WYCO NT1000 instrument signal near a carefully created edge on the sample surface obtained in Example 6.

FIG. 6B shows a X-ray diffraction pattern of the film obtained in Example 6.

### DETAILED DESCRIPTION OF THE INVENTION

Materials in their solid state are known to have different degrees of order in the arrangement of its constituents. Highly ordered solids are crystalline and those crystals may have a variety of sizes and shapes. Crystalline solids have a sharp melting point. Highly disordered solids are amorphous. They are commonly called glassy solids. They have molecular structure of liquids but have properties (e.g., viscosity, thermal expansion, specific heat etc.) like solids. In a sense, they are cooled liquids where molecular motion of liquid is brought to a halt due to cooling. When amorphous materials are heated, their properties start becoming liquid-like beyond a certain temperature. This is commonly called the glass transition temperature, Tg. With further increase in temperature over a range, the material increasingly becomes more liquid-like, eventually melting fully at its melting point. In this state between the glass transition temperature and the melting temperature, solids behave like liquids with very high viscosity.

In accordance with this invention, it has been unexpectedly found that amorphous solid particles of a desired substance, suspended in a carrier gas, can be deposited to form a uniform thin film after heating them above their Tg and directing the flow to a receiver surface that is at a temperature lower than the heated flow. The volume averaged particle diameter for such particles employed in the process of the invention is below 500 nm, more preferably below 100 nm, most preferably below 10 nm. Lower particle size is desired for higher coating surface smoothness and ability to coat higher quality films where film thickness is, e.g., less than 10 micrometer, preferably below 1 micrometer, and more preferably below 0.5 micrometer. Also, it is known that particles begin to melt at their surfaces at temperature lower than its bulk (see, for example, P. Tibbits et al. in J. Vac. Sci. Technol. (1991)A9(3):1937). A similar phenomenon may also lower the effective glass transition temperature for nano-scale particles employed in the present invention, enabling the process to be effective at lower heating temperatures than may be required for processes employing larger size particles in coating applications. Also, the melting behavior of the particle is significantly affected by the contacting substrate (see for example, V. Storozhev in Surface Science (1998) 397:170-178).

The process of the invention is applicable to the preparation of coatings of a wide variety of materials for use in, e.g., pharmaceutical, agricultural, food, chemical, imaging (including photographic and printing, and in particular inkjet printing), cosmetics, electronics (including electronic display device applications, and in particular color filter arrays and organic light emitting diode display devices), data recording, catalysts, polymer (including polymer filler applications), pesticides, explosives, and microstructure/nanostructure architecture building, all of which can benefit from use of continuous small particulate material coating processes. Materials of a desired substance coated in accordance with the invention may be of the types such as organic (including metallo-organic), inorganic, polymeric, oligomeric, ceramic, metallo-ceramic, metals, a synthetic and/or natural polymer, and a composite material of these previously mentioned. Coated materials can be, for example colorants (including dyes and pigments), agricultural chemicals, commercial chemicals, fine chemicals, pharmaceutically useful compounds, food items, nutrients, pesticides, photographic chemicals, explosive, cosmetics, protective agents, metal coating precursor, or other industrial substances whose desired form is that of a deposited film or coating. Organic materials are particularly preferred functional materials for use in coating applications in accordance with the invention.

The carrier gas may be air, CO₂, CO, inert gases like N₂, He, Ar, Xe, or suitable mixture thereof. In addition, a wide variety of compressed fluids known in the art, and in particular supercritical fluids (e.g., CO₂, NH₃, H₂O, N₂O, ethane etc.), may in their expanded state, be considered for such a selection, with supercritical CO₂ being generally preferred. Similarly, a wide variety of commonly used carrier solvents (e.g., ethanol, methanol, water, methylene chloride, acetone, toluene, dimethyl formamide, tetrahydrofuran, etc.) may also be present as minor components. Since any such solvents are intended to be in the gaseous state during the deposition of the desired material, solvents with higher volatility at lower temperatures are more desired.

Continuous sources of desired particle laden gas flow which may be employed in this invention include, without limitations, flow exiting from any suitably designed nozzle that mixes the carrier gas with the solid particles, for example, spray nozzles useful in thermal spray or powder coating applications; modules described in U.S. Pat. No. 6,511,149 for combining the propellant gas and marking material in a ballistic aerosol marking system; and outlet of an aerosol generator or concentrator. In accordance with a preferred embodiment, the stream of particles of a desired substance suspended in a carrier gas may be obtained from the final expansion nozzle of a supercritical fluid based particle formation system, such as a rapid expansion of supercritical solution (RESS) type system or a supercritical anti-solvent (SAS) type system, and more preferably from a SAS type system such as described, for example, in commonly assigned U.S. Ser. No. 10/815,026 (Docket 87485) and U.S. Ser. No. 10/814,354 (Docket 86430), the disclosures of which are incorporated by reference herein.

When employing a SAS type process, the stream may be prepared under essentially steady state conditions by precipitation of the desired substance from a solution upon contact with a compressed fluid antisolvent in a particle formation vessel and exhaustion of the particle and compressed fluid from the vessel through an expansion nozzle. As in known SAS type processes, solvents for use in such embodiment of the present invention may be selected based on ability to dissolve the desired material, miscibility with a compressed fluid antisolvent, toxicity, cost, and other factors. The solvent/solute solution is then contacted with a compressed fluid antisolvent in a particle formation vessel, the temperature and pressure in which are controlled, where the compressed fluid is selected based on its solubility with the solvent and relative insolubility of the desired particulate material (compared to its solubility in the solvent), so as to initiate precipitation of the solute from the solvent upon rapid extraction of the solvent into the compressed fluid. The functional material to be deposited has a relatively higher solubility in the carrier solvent than in the compressed fluid or than in the mixture of compressed fluid and the carrier solvent. This enables the creation of a high supersaturation zone in the vicinity of the introduction point where the solution of functional material in the carrier solvent is added into the particle formation vessel. A wide variety of compressed fluids known in the art, and in particular supercritical fluids (e.g., CO₂, NH₃, H₂O, N₂O, ethane etc.), may be considered in such a selection, with supercritical CO₂ being generally preferred. Similarly, a wide variety of commonly used carrier solvents (e.g., ethanol, methanol, water, methylene chloride, acetone, toluene, dimethyl formamide, tetrahydrofuran, etc.) may be considered. Since, eventually both the compressed fluid and the carrier solvent are intended to be in the gaseous state, carrier solvents with higher volatility at lower temperatures are more desired. The relative solubility of functional material can also be adjusted by appropriate choice of pressure and temperature in the particle formation vessel.

Feed materials should be adequately mixed with the vessel contents upon their introduction into the vessel, such that the carrier solvent and desired substance contained therein are dispersed in the compressed fluid, allowing extraction of the solvent into the compressed fluid and precipitation of particles of the desired substance. This mixing may be accomplished by the velocity of the flow at the introduction point, or through the impingement of feeds on to another or on a surface, or through provision of additional energy through devices such as a rotary mixer, or through ultrasonic vibration. It is desirable that the entire content of the particle formation vessel is maintained as close to a uniform concentration of particles as possible. The spatial zone of non-uniformity near the feed introduction should also be minimized. Inadequate mixing process may lead to an inferior control of particle characteristics. Thus, feed introduction into a region of high agitation, and the maintenance of a generally well-mixed bulk region is preferred. Most preferably, the solvent/desired substance solution and compressed fluid antisolvent are contacted in a particle formation vessel by introducing feed streams of such components into a highly agitated zone of the particle formation vessel, such that the first solvent/solute feed stream is dispersed in the compressed fluid by action of a rotary agitator as described in copending, commonly assigned U.S. Ser. No. 10/814,354 (Docket 86430), the disclosure of which is also incorporated by reference herein. As described in such copending application, effective micro and meso mixing, and resulting intimate contact of the feed stream components, enabled by the introduction of the feed streams into the vessel within a distance of one impeller diameter from the surface of the impeller of the rotary agitator, enable precipitations of particles of the desired substance in the particle formation vessel with a volume-weighted average diameter of less than 100 nanometers, preferably less than 50 nanometers, and most preferably less than 10 nanometers. In addition, a narrow size-frequency distribution for the particles may be obtained. The measure of the volume-weighted size-frequency distribution, or coefficient of variation (mean diameter of the distribution divided by the standard deviation of the distribution), e.g., is typically 50% or less, with coefficients of variation of even less than 20% being enabled. The size-frequency distribution may therefore be monodisperse. Process conditions may be controlled in the particle formation vessel, and changed when desired, to vary particle size as desired. Preferred mixing apparatus which may be used in accordance with such embodiment includes rotary agitators of the type which have been previously disclosed for use in the photographic silver halide emulsion art for precipitating silver halide particles by reaction of simultaneously introduced silver and halide salt solution feed streams. Such rotary agitators may include, e.g., turbines, marine propellers, discs, and other mixing impellers known in the art (see, e.g., U.S. Pat. No. 3,415,650; U.S. Pat. No. 6,513,965, U.S. Pat. No. 6,422,736; U.S. Pat. No. 5,690,428, U.S. Pat. No. 5,334,359, U.S. Pat. No. 4,289,733; U.S. Pat. No. 5,096,690; U.S. Pat. No. 4,666,669, EP 1156875, WO-0160511). Mixing apparatus which may be employed in one particular embodiment of the invention also includes mixing devices of the type disclosed in Research Disclosure, Vol. 382, February 1996, Item 38213, as well as in U.S. Pat. No. 6,422,736, the disclosures of which are incorporated by reference.

Regardless of the particular source of desired particle laden gas flow employed in the present invention, the pressure and temperature of the flow are preferably maintained such that any solvent is substantially in its gas or vapor state and simultaneously the particle temperature is below its Tg prior to passing through a subsequent heating means in accordance with the invention. Depending on the intended applications, the source stream pressure can range from several atmospheres to very high vacuum, and the source stream flow velocity may range from being supersonic to subsonic. The invention is particular advantaged, however, in enabling the effective coating of fine particulate materials entrained in a carrier fluid which is at near atmospheric pressure and at subsonic flow velocities.

The flow stream is then heated by a heating means. The heating means may include all suitable heating devices, including, but without limitations, an electric heater; a heated wall heat exchanger; a packed bed heater; a microwave heater; a plasma flame; a laser beam; and an inert hot gas that is directly mixed. The pressure and temperature of the flow are preferably maintained such that any solvent is substantially in its gas or vapor state, while simultaneously heating the particle temperature to above its Tg at the outlet of the heating means. It is preferred that the particle temperature stays below a value that ensures no substantial chemical modification of the particles or the surrounding gaseous material occurs, however, so as to avoid any detrimental effect on the coatings made downstream. In preferred embodiments, the temperature of the stream is also maintained such that the suspended particles are below their melting point as they leave the heated zone. Depending on the specific heating means used, the residence time of the flow stream in the heated zone may range from minutes to nanoseconds.

The effluent from the heating means is then passed through a flow distribution means at a rate substantially equal to the rate of addition of the stream to the heating zone. The distribution means may include, without limitations, suitably designed single or multiple conduits; apertures; and slots, that are in direct communication with the heating means, so as to direct the flow of effluents onto the receiver in a desired manner. In accordance with the present invention, the carrier gas does not undergo a thermodynamic phase change upon passage through heating zone and distribution passage, and thus the present invention is distinguished from heating of a supercritical fluid expansion valve. The distribution means may also include valves or shutters for controlled delivery of flow with time.

The receiver surface to be coated is located downstream of the distribution means, preferably at a distance and temperature determined experimentally to achieve the desired material deposition efficiency and film 30 quality. The receiver surface will be at a temperature below the temperature of the heated stream, and preferably below the glass transition temperature of the desired material particles. Regardless of the receiver surface temperature, the distance between the distribution means and the receiver surface should preferably be maintained such that excessive cooling of the heated stream does not occur to an extent such that the desired material particles are cooled to below their Tg prior to contacting the receiver surface. In preferred embodiments, the receiver surface is maintained within 5 cm of the outlet of the distribution means, more preferably within 3 cm, and most preferably within 1 cm. By requiring the temperature of the nanoparticles to be above the Tg of the functional material particles, and that of the receiver surface to be below such Tg, the particles' affinity to adhere to the receiver surface is enhanced. Thus, such embodiment of the invention facilitates the formation of a thin film once the nanoparticles of functional material arrive at the receiver surface.

Subject to the above-described requirements, flow exiting from the distribution means may be directly used for coating the functional material onto a receiver substrate that is at ambient temperature. More preferably, however, the deposition surface is actively cooled to keep it at a temperature lower than the impinging gas stream temperature. In case of multilayer coatings, the deposition surface temperature should also be kept at or below the Tg of the material in the underlying layer to mitigate any adverse interfacial effects in the final composite film structure. In particular, the temperature of the deposition surface may be controlled to enhance the adhesion between layers of dissimilar materials or improve cohesion among layers of similar materials. Active cooling may be achieved by keeping a conventional cooling platen in close thermal contact underneath the receiver surface or with a moving substrate, for example, a roll-to roll web coating surface, or combination thereof. Using a cold environmental gas that does not chemically interfere may also help achieve practical cooling rates. In one preferred embodiment, the deposition surface is kept at a temperature substantially below the Tg of the functional material and simultaneously above the boiling point of any component organic solvent present in the heated stream. Such conditions substantially mitigate the role of the solvent molecules in film formation.

Depending on the dominant deposition mechanism, it may be advantageous to maximize the spatial temperature gradient at the deposition surface for improved deposition efficiency. For example, such conditions are known to improve thermophoretic deposition of nanoparticles. The phenomenon of thermophoresis causes small particles to be driven away from a hot surface towards a cold one (see, for example, Zheng F. in Adv. in Coll. & Interface Sci. (2002) 97:253-276). Depending on the specific application, a temperature gradient of greater than 10 degree C./mm to greater than 10⁵ degree C./mm may be desired. In another preferred embodiment the deposited material may be cooled rapidly to essentially keep the deposited particles amorphous. Depending on the specific application, preferred cooling rate may range from greater than 10 degree C./sec to greater than 10⁶ C./sec.

In a particular embodiment of the invention, the receiver surface may moved in relation to the exhausted flow of the heated stream to form the thin uniform layer of the desired material on the receiver surface. Such relative movement may be achieved, e.g., by employing a continuous moving substrate which passes through a deposition zone as the receiver surface, and/or by moving the flow distribution means relative to the receiver surface. It may also be advantageous to move the receiver surface in and out of the deposition zone at a desired rate to manage the interfacial temperature and temperature gradient at the deposition surface. The rate of movement can be determined beneficially by taking into account the gas flow, and the impingement geometry, and the ambient environment. Alternatively, a shutter type arrangement may be employed to provide multiple exposures of substrate to the deposition zone to build the desired coating or film thickness while maintaining the temperature in the desired range. Additional electromagnetic or electrostatic means may also be used to interact with the exhaust from the distributor means to deflect the flow of functional material to the coating surface and enhance the material deposition rate. This includes electrostatic techniques such as induction, corona charging, charge injection or tribo-charging.

The invention enables thin material films to be deposited at ambient or near ambient (e.g., within 10 percent of ambient) conditions of pressure, with an average surface roughness of less than 10 nm, preferably less than 5 nm, and even more preferably less than 0.5 nm, where the average surface roughness value is calculated by WYCO NT1000 as the arithmetic average of the absolute values of the surface features from the mean plane. Additional flow means may also be similarly employed to either control the momentum, or temperature, of the deposition flow stream. The coating surface may also be either treated (uniformly or patterned) before or during deposition to enhance the particle deposition efficiency. For example, coating surface may be exposed to plasma or corona discharges to improve adhesion of depositing particles. Similarly, coating surfaces may be pre-patterned to have regions of relatively high or low conductivity (e.g., electrical, thermal, etc.), or regions of relatively high or low lyo- (e.g., hydro-, lipo-, oleo-, etc.) phobicity, or regions of relatively high or low permeability. In certain web coating applications or applications consisting of moving surfaces, more precise downstream applicator nozzles are also envisioned. The flow through these downstream applicator nozzles is preferably subsonic.

An additional feature for web or continuous coating applications is containment of the solvent vapors and particles that are not coated. This may be achieved by an enclosure that houses the coating station. Alternatively, a curtain of inert gases can also provide a sealing interface. Such an arrangement allows a highly compact apparatus for such applications. In certain applications, it may be advantageous to have additional post-coating processing capabilities such as heating or exposing to specific atmosphere. Similarly, multiple coating applicators may also be sequenced to create suitable multi-layer film architectures. A further aspect of manufacturing scale processes is recycling of processing fluids. This entails separation of carrier solvent vapors from the exhaust stream through condensation, a process that may also be used to trap and re-dissolve uncoated particles. The exhaust stream then could be recompressed and recycled as compressed fluid.

### EXAMPLE 1

### Control

A SAS type particle generation process of the type disclosed in copending, commonly assigned U.S. Ser. No. 10/814,354 (Docket 86430) was employed to generate a desired gaseous flow stream. A nominally 1800 ml stainless steel particle formation vessel was fitted with a 4 cm diameter agitator of the type disclosed in U.S. Pat. No. 6,422,736, comprising a draft tube and bottom and top impellers. CO₂ was added to the particle formation vessel while adjusting temperature to 90 C and pressure to 300 Bar and while stirring at 2775 revolutions per minute. The addition of CO₂ at 60 g/min through a feed port that had a 200 μM orifice at its tip, and a 0.1 wt % solution of Tert-Butyl-anthracene di-naphthylene (TBADN: a functional material used in Organic Light Emitting Diodes) in acetone at 3 g/min, through a 100 μm tip, was then commenced and the process was allowed reach a steady state. The CO₂ and solution feed ports were located close to the bottom impeller as disclosed for the inlet tubes for the mixer, such that both the solution and the CO₂ feed streams were introduced into a highly agitated zone within one impeller diameter of the bottom impeller. As disclosed in U.S. Ser. No. 10/814,354, such process has been found to typically result in formation of particles having sizes less than 10 nm.

The outlet port of the particle formation vessel was connected to a first backpressure regulator. A stainless steel pre-filter, whose nominal filtration efficiency for 0.5 μm particles was 90%, was placed upstream of the first backpressure regulator. The output of the first regulator was connected to a compressed flow heater that heated the flow to 90 C before sending it forward to a second backpressure regulator. The compressed flow mixture expanded to a pressure of less than 2 Bar downstream of the secondary regulator and its temperature was at 58 degree C. Tg of TBADN is 130 C and melting point of bulk TBADN powder is 290 C. Boiling point of acetone is about 56 C at 1 Bar. The flow then passed through an annular heat exchanger that had a central core and an outer annular spiral passageway surrounding the central core through which the flow passed. The heat exchanger was directly in communication with a stainless steel slot placed downstream of the heat exchanger. The slot was 203 μm wide and 2.54 cm long. The heat exchanger was not powered for this experiment. The mean temperature of the gaseous flow exiting the slot under ambient pressure for the duration of the experiment was 43 C. The coating substrate was kept 7.62 mm away from the slot. The underside of the substrate was maintained at 10 C. The coating substrate could be moved back and forth under the slot at predetermined speed. The flow of exhausted material moved nominally parallel to the substrate after the impingement and then went to a vent that had a low level of suction (less than 5 torr below ambient) to aid the flow.

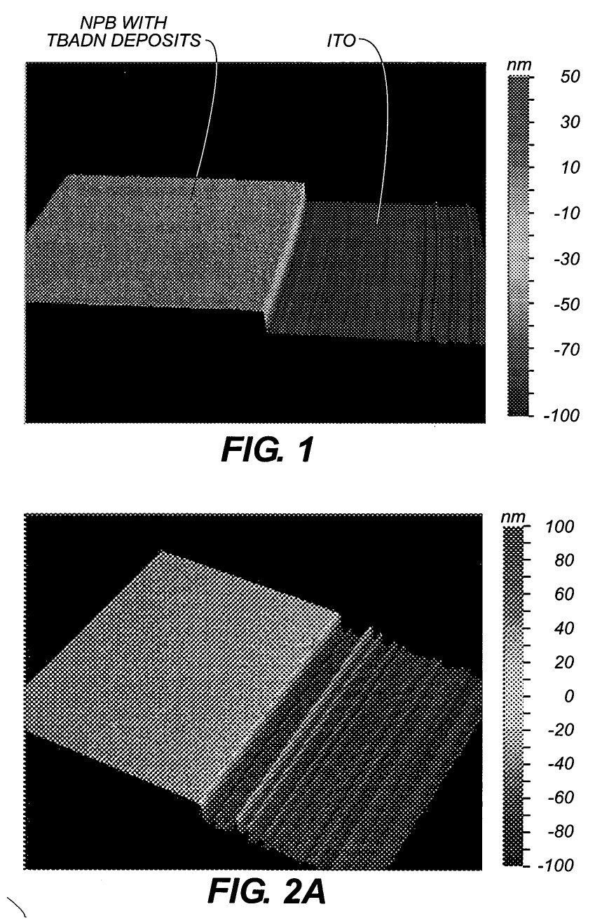

After the system reached steady state conditions of temperature and pressure, a 2.5″×2.5″ glass slide, pre-coated first with a 40 nm film of indium tin oxide (ITO) and then an overlaying 84 nm film of N,N′-di(naphthalene-1-yl)-N,N′-diphenyl-benzidine (NPB) (a hole-transport material used in Organic Light Emitting Diodes and was deposited via a conventional vacuum deposition method), was placed on the coating surface as the coating substrate. The surface was passed 300 times under the coating slot at a speed of 10 ft/min. The resultant coating was then subjected to various characterization methods to elucidate its features. First, an edge was created carefully on the deposition surface. The coating was then coated with 2 nm thick gold film under vacuum and examined by Vertical Scanning Interferometry with a non-contact optical profilometer (WYCO NT1000 from Veeco Instruments) at a surface magnification of 10×. FIG. 1 shows the 3-dimensional display of the sample surface. The lower level of the signal corresponds to the ITO film surface. The higher level corresponds to the NPB layer and thin, discontinuous deposits of TBADN on its surface. Thus, when the flow stream is not heated above the Tg of the TBADN particles downstream of the secondary regulator, a discontinuous coating of TBADN is formed on the underlying NPB film.

### EXAMPLE 2

### Invention

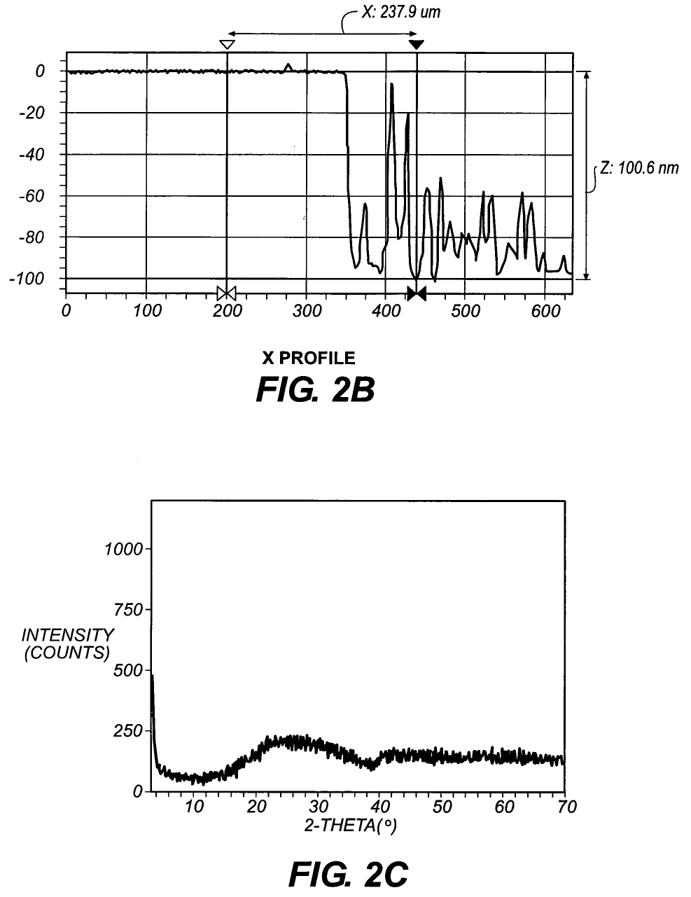

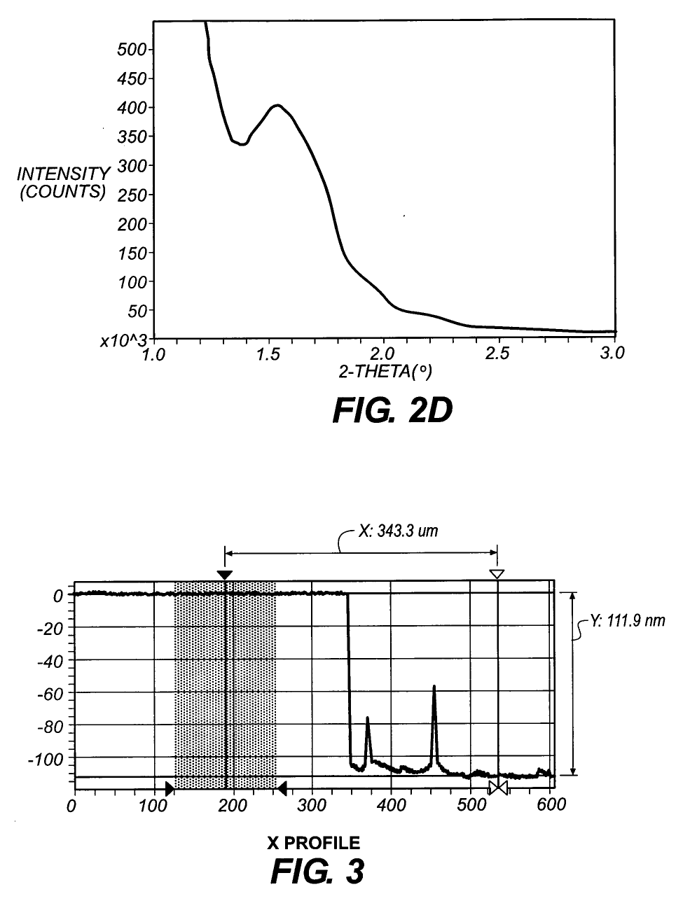

The procedure employed in Example 1 was repeated, except that the heat exchanger was powered such that the temperature of the gaseous flow exiting the slot under ambient pressure was 193 C, above the Tg of the generated TBADN particles. The resultant coating was then subjected to various characterization methods to elucidate its features. First, an edge was created carefully on the deposition surface. The coating was then coated with 2 nm thick gold film under vacuum and examined by Vertical Scanning Interferometry with a non-contact optical profilometer (WYCO NT1000 from Veeco Instruments) at a surface magnification of 10×. FIG. 2(A) shows the 3-dimensional display of the sample surface. The lower level of the signal corresponds to the ITO film surface. The higher level corresponds to the NPB layer and thin, continuous deposits of TBADN on its surface. FIG. 2(B) shows the instrument signal near the carefully created edge on the deposition surface. The lower level of the signal corresponds to the ITO film surface. The higher level corresponds to the deposited layer. It shows a nominal layer thickness of 100.8 nm, and a layer that is also continuous. When the thickness of the underlying organic layer (NPB) is subtracted, a TBADN film thickness of 16.3 nm is measured. The average surface roughness of the 16.3 nm thick layer was 0.39 nm, calculated by WYCO NT1000 as the arithmetic average of the absolute values of the surface features from the mean plane. FIG. 2(C) is a high-angle X-ray diffraction pattern of the film showing its amorphous nature. FIG. 2(D) is a low-angle X-ray diffraction pattern of the film showing distinct order (peak at 1.5 2-Theta) with a spacing of 5.8 nm based on Bragg's law. Such spacing is further indicative of the film being formed from particles of size less than 10 nm. Thus a highly structured nanothin film is produced.

### EXAMPLE 3

### Invention

The procedure employed in Example 2 was repeated, except that the temperature of the flow at the coating slot was maintained at 222 degree C. and the substrate was passed 360 times under the coating slot. The resulting coating on the glass slide was also similarly examined by interferometry. After subtracting the thickness of underlaying NPB layer (84 nm), the TBADN film thickness was estimated to be 28 nm from FIG. 3. The surface roughness was 0.34 nm.

### EXAMPLE 4

### Invention

The procedure employed in Example 2 was repeated, except that the temperature of the flow at the coating slot was maintained at 250 C and the substrate was passed 400 times under the coating slot. The resulting coating on the glass slide was also similarly examined by interferometry. After subtracting the thickness of underlaying NPB layer (84 nm), the TBADN film thickness was estimated to be 79 nm from FIG. 4. The surface roughness was 0.97 nm.

### EXAMPLE 5

### Invention

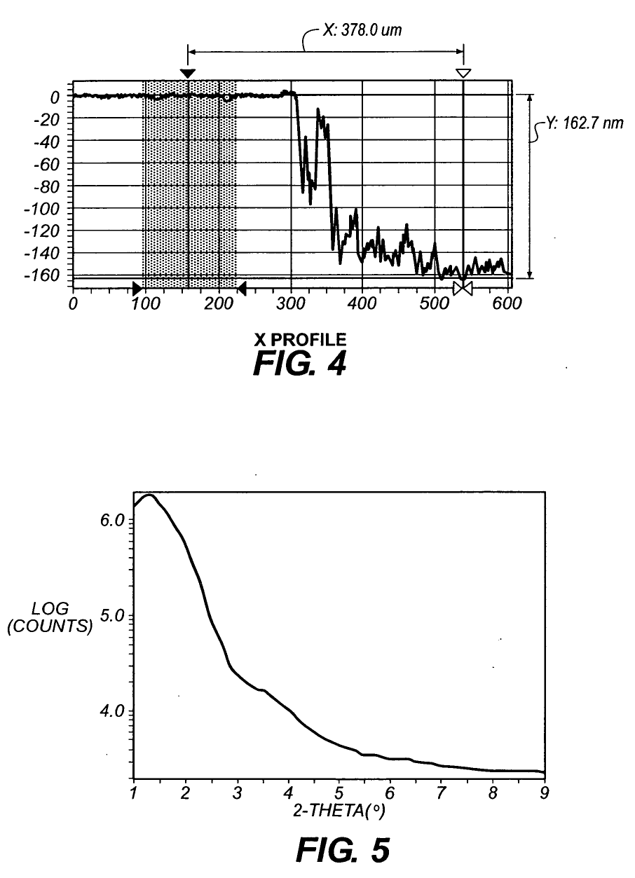

The procedure employed in Example 4 was repeated with the following exceptions: the temperature of the particle formation vessel was maintained at 55 C; the CO₂ and acetone solution flow rates were 100 g/min and 5 g/min, respectively; the substrate was passed 120 times under the coating slot at 2.5 ft/min; and the underside of the substrate was maintained at 0 C. The resulting film on the NPB coated glass slide was then examined by X-ray diffraction. The high angle X-ray diffraction pattern for the film indicated that no crystalline phase due to the organic film was present. However, the low angle X-ray diffraction pattern (FIG. 5) for the film revealed a peak that corresponded to a long-range order spacing of 2.47 nm (again indicative of a film formed from particles having a size of less than 10 nm).

### EXAMPLE 6

### Invention

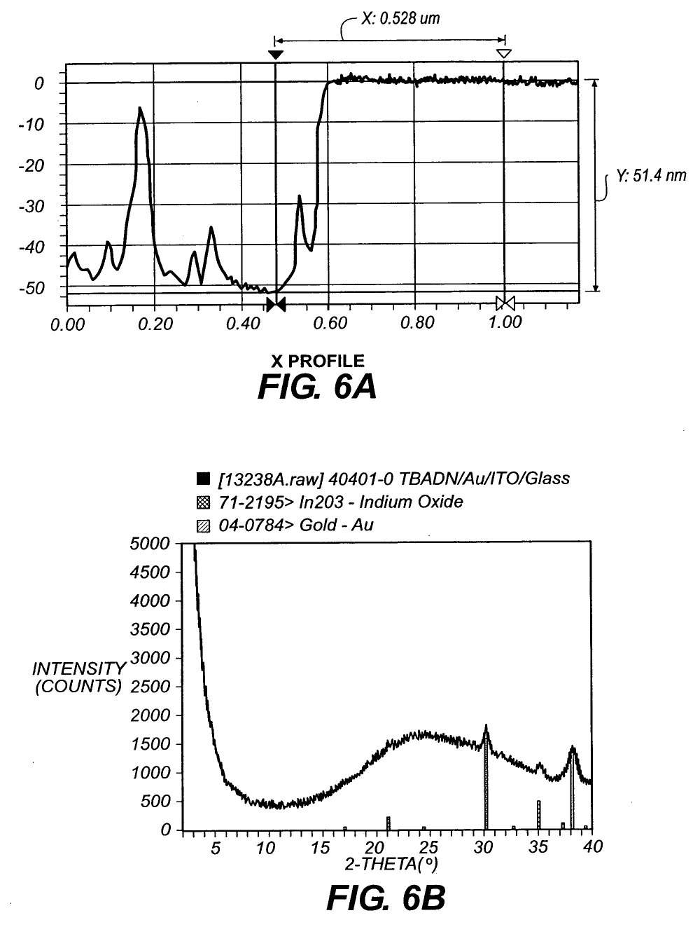

The procedure employed in Example 2 was repeated, with the following exceptions: CO₂ flow rate=40 g/min, flow rate of 0.01 wt % TBADN solution in acetone=2 g/min, pressure in the particle formation vessel=250 bar, temperature of flow exiting the coating slot=310 C, coating slot dimensions: 607 μm wide and 7.62 cm long, gap between coating slot and coating substrate=762 μm, number of passes of coating substrate under the slot=216, speed of coating substrate=2.5 ft/min, temperature of the underside of coating substrate=40 C, and the substrate was a glass slide pre-coated only with 50 nm film of ITO. The resulting coating on the glass slide was also similarly examined by interferometry. FIG. 6A shows that film thickness was 51.4 nm. The film surface roughness was measured to be 0.43 nm. FIG. 6B is an X-ray diffraction (XRD) plot of the film. XRD detected crystalline peaks for metallic gold and the ITO layer with the In₂O₃ crystalline structure, plus an amorphous area centered around 24 degrees 2-theta that is normally associated with amorphous glass. No peaks due to crystallinity of the TBADN film were detected. No peaks due to long-range periodicity due to the TBADN film were detected. Thus, the film was found to be amorphous.

### EXAMPLE 7

### Invention

The procedure employed in Example 2 was repeated, except that the temperature of the flow at the coating slot was maintained at 250 C, the substrate was a glass slide partially pre-coated with 50 nm thick film of ITO, and the substrate was passed 300 times under the coating slot. The resulting coating on the glass slide was similarly examined by interferometry. The TBADN film thickness was estimated to be 14 nm on glass with a surface roughness of 0.31 nm, and 13 nm on ITO with a surface roughness of 0.34 nm.

It is thus found that the disclosed process provides high quality uniform, continuous, ultrathin, amorphous films of organic material on inorganic (e.g., ITO, glass), and organic (e.g., NPB) surfaces at high deposition rates. Such films also have long-range periodicity when deposited on an organic surface.

It is to be understood that elements not specifically shown or described may take various forms well known to those skilled in the art. Additionally, materials identified as suitable for various facets of the invention are not limiting. These are to be treated as exemplary, and are not intended to limit the scope of the invention in any manner.

1. A process for the deposition of a thin film of a desired material on a surface comprising:
(i) providing a continuous stream of amorphous solid particles of desired material suspended in at least one carrier gas, the solid particles having a volume-weighted mean particle diameter of less than 500 nm, at an average stream temperature below the glass transition temperature of the solid particles of desired material,
(ii) passing the stream provided in (i) into a heating zone, and heating the stream in the heating zone to elevate the average stream temperature to above the glass transition temperature of the solid particles of desired material, wherein no substantial chemical transformation of the desired material occurs due to heating of the desired material,
(iii) exhausting the heated stream from the heating zone through at least one distributing passage, at a rate substantially equal to its rate of addition to the heating zone in step (ii), wherein the carrier gas does not undergo a thermodynamic phase change upon passage through heating zone and distribution passage, and
(iv) exposing a receiver surface that is at a temperature below the temperature of the heated stream to the exhausted flow of the heated stream, and depositing particles of the desired material to form a thin uniform layer of the desired material on the receiver surface.

2. A process according to claim 1, wherein the desired material comprises an organic compound, and the continuous stream of solid particles of desired material suspended in at least one carrier gas is generated by a supercritical fluid based process.

3. A process according to claim 2, wherein a supercritical fluid is employed as an anti-solvent in the supercritical fluid based process, and the continuous stream of particles of desired material suspended in at least one carrier gas passed into a heating zone in (ii) is prepared under essentially steady state conditions by precipitation of the desired substance from a solution upon contact with the supercritical fluid antisolvent in a particle formation vessel and exhaustion of the particle and supercritical fluid from the vessel through an expansion nozzle.

4. A process according to claim 3, wherein supercritical fluid contains at least carbon dioxide.

5. A process according to claim 4, wherein the coefficient of variation of the particle size distribution of the particles of the desired material generated in the supercritical fluid based process is less than 50%.

6. A process according to claim 4, wherein particles of the desired material have a volume-weighted average diameter of less than 100 nanometers.

7. A process according to claim 4, wherein particles of the desired material have a volume-weighted average diameter of less than 10 nanometers.

8. A process according to claim 4, where the uniform layer deposited in step (iv) is a continuous film having a thickness of less than 1 micrometer.

9. A process according to claim 8, where the continuous film is amorphous.

10. A process according to claim 9, where the receiver surface is made from an organic material and the amorphous film deposited thereon has long-range order.

11. A process according to claim 10, where the receiver surface comprises an organic compound used to make electroluminescent devices.

12. A process according to claim 10, where the magnitude of spacing for the long-range order is greater than 1 nm.

13. A process according to claim 9 in which the film is deposited at ambient or near ambient conditions of pressure.

14. A process according to claim 9 in which the film has an average surface roughness of less than 5 nm, calculated by WYCO NT1000 as the arithmetic average of the absolute values of the surface features from the mean plane.

15. A process according to claim 9 in which the film has an average surface roughness of less than 0.5 nm, calculated by WYCO NT1000 as the arithmetic average of the absolute values of the surface features from the mean plane.

16. A process according to claim 1, wherein the average stream temperature is maintained below the melting point temperature of the desired material.

17. A process according to claim 1, where the desired substance comprises a compound used to make organic electroluminescent devices.

18. A process according to claim 1, wherein the receiver surface is at a temperature below the glass transition temperature of the solid particles of desired material.

19. A process according to claim 1, wherein the receiver surface is maintained within 3 cm of the outlet of the distributing passage.

20. A process according to claim 1, wherein the receiver surface is moved in relation to the exhausted flow of the heated stream to form the thin uniform layer of the desired material on the receiver surface.
